(19) United States
(12) Patent Application Publication
(10) Pub. No.: US 2022/0098737 A1
(43) Pub. Date: Mar. 31, 2022

(54) SHOWERHEAD AND SUBSTRATE PROCESSING APPARATUS HAVING THE SAME

(71) Applicant: JUSUNG ENGINEERING CO., LTD., Gwangju-si, Gyeonggi-do (KR)

(72) Inventors: Ram WOO, Gwangju-si, Gyeonggi-do (KR); Ki Bum KIM, Gwangju-si, Gyeonggi-do (KR); Jae Hong KIM, Gwangju-si, Gyeonggi-do (KR); Gil Je LEE, Gwangju-si, Gyeonggi-do (KR); Ju Young LEE, Gwangju-si, Gyeonggi-do (KR); Yun Gyu HA, Daegu (KR)

(21) Appl. No.: 17/427,080

(22) PCT Filed: Dec. 3, 2019
(86) PCT No.: PCT/KR2019/016913

§ 371 Date: Jul. 29, 2021

(30) Foreign Application Priority Data
Jan. 29, 2019 (KR) 10-2019-0010858

(51) Int. Cl. C23C 16/455; H01J 37/32; C23C 16/458; C23C 16/50

(52) U.S. Cl. CPC C23C 16/45565; H01J 37/3244; H01J 2237/3321; C23C 16/50; C23C 16/4583

(57) ABSTRACT

The present disclosure relates to a shower head which is fixed to a sidewall through a coupling unit and can prevent a separation from the sidewall, and a substrate processing apparatus including the same.

The shower head may be fixed to the sidewall through the coupling unit. Therefore, a second end part of the coupling unit can prevent the coupling unit from falling out of an assist groove, even though the diameter of the assist groove is increased by thermal expansion, which makes it possible to increase a coupling force between the sidewall and the shower head. Furthermore, even when a repair work is performed, the assist groove is not widened. Although only the second end part of the coupling unit is cut, the sidewall can be easily replaced.

### BACKGROUND

### 1. Technical Field

The present disclosure relates to a shower head for supplying gas to a reaction space within a substrate processing apparatus and a substrate processing apparatus having the same, and more particularly, to a shower head which is fixed to a sidewall through an oarlock in order to prevent a separation of the shower head from the sidewall, and a substrate processing apparatus having the same.

### 2. Related Art

In general, a predetermined circuit pattern or optical pattern needs to be formed on the surface of a substrate, in order to fabricate a semiconductor device, a flat display panel, a solar cell or the like. For this operation, a substrate processing process is performed within a substrate processing apparatus. The substrate processing process includes a thin film deposition process of depositing a specific material of thin film on the substrate, a photo process of selectively exposing the thin film using a photosensitive material, and an etch process of forming a pattern by removing the selectively exposed region of the thin film.

Such a semiconductor fabrication process is performed within the substrate processing apparatus which is designed to have the optimal environment for the corresponding process. Recently, a substrate processing apparatus which performs a deposition or etch process using plasma is widely used.

The substrate processing apparatus using plasma includes a PECVD (Plasma Enhanced Chemical Vapor Deposition) apparatus which forms a thin film using plasma and a plasma etching apparatus which etches and patterns a thin film.

FIG. 1 is a cross-sectional view illustrating an embodiment of a substrate processing apparatus using plasma according to the related art.

Referring to FIG. 1, the conventional substrate processing apparatus includes a chamber 10, an upper lid 20, a susceptor 30, a shower head 40 and a sidewall 50.

The chamber 10 provides a reaction space for a substrate processing process. At this time, one side of the bottom surface of the chamber 10 communicates with an exhaust port 12 for exhausting gas from the reaction space.

The upper lid 20 is installed at the top of the chamber 10 so as to seal the reaction space, and serves as a plasma electrode in the substrate processing apparatus using plasma. One side of the upper lid 20 is electrically connected to an RF (Radio Frequency) power supply 23 through a power cable. At this time, the RF power supply 24 generates RF power and supplies the generated RF power to the upper lid 20 serving as the plasma electrode. Furthermore, the central portion of the upper lid 20 communicates with a gas supply pipe 26 that supplies process gas for the substrate processing process.

The susceptor 30 is installed in the chamber 10, and supports a substrate S supplied from the outside. Such a susceptor 30 is a counter electrode facing the upper lid 20, and is electrically grounded through a support shaft 32 that supports the susceptor 30. At this time, the support shaft 32 is surrounded by a bellows 34 that seals the support shaft 32 and the bottom surface of the chamber 10.

The shower head 40 is installed under the upper lid 20 so as to face the susceptor 30. Between the shower head 40 and the upper lid 20, a gas buffer space 42 is formed, to which process gas is supplied through the gas supply pipe 26 installed through the upper lid 20. At this time, the process gas is supplied as a gas mixture to the gas buffer space 42, the gas mixture being obtained by mixing reaction gas and source gas for forming a predetermined thin film on the substrate S. Such a shower head 40 injects the process gas into the reaction space through a plurality of gas injection holes 44 communicating with the gas buffer space 42.

The sidewall 50 has a first end part 51 fixed to the upper lid 20 and a second end part 53 supporting the shower head 40, and the first and second end parts 51 and 53 are connected by a connection part 52.

In general, the shower head 40 is robustly mounted on the upper lid 20 or an upper wall surface of the chamber 10. However, when the shower head 40 is robustly mounted on the upper lid 20 or the upper wall surface of the chamber 10, continuous thermal stress is applied to the shower head 40 in the case that the shower head 40 is thermally expanded by heat supplied from plasma. Such thermal stress may damage the shower head 40.

Therefore, a conventional method has been suggested, which can improve the structure of the sidewall 50 to have flexibility, and thus minimize thermal stress by thermal expansion and contraction, which is applied to the shower head 40.

FIGS. 2A and 2B are diagrams for describing the structure of the sidewall and the coupling between the sidewall and the shower head according to the related art.

Referring to FIGS. 2A and 2B, the sidewall according to the related art has a structure in which the first end part 51, a center part 52 and the second end part 53 form a zigzag shape.

At this time, the first end part 51 is fixed to the bottom surface of the upper lid 20 by a bolt 51a, and the second end part 53 is fixed to the shower head 40 and supports the shower head 40. The connection part 52 has flexibility to minimize mechanical stress by thermal expansion when the shower head is thermally expanded.

FIG. 2A illustrates that the second end part 53 of the sidewall is fixed to the shower head 40 through a pin 61. Specifically, the second end part 53 of the sidewall is fitted into a corresponding groove of the shower head 40, and the pin 61 is then inserted into a pin insertion hole to fix the sidewall and the shower head.

However, as the pin insertion hole is widened by thermal expansion, the pin may fall out. Thus, a process of fixing the pin inserted into the pin insertion hole to the shower head through welding is additionally required in order to prevent the pin from falling out.

FIG. 2B illustrates that the second end part 53 of the side wall is fixed to the shower head through a rivet 62. Specifically, the second end part 53 of the sidewall and the shower head are aligned with each other, a rivet insertion hole is bored, and the rivet is inserted into the rivet insertion hole. Then, when a shim within the rivet is pulled by a tool, an end portion of the shim within the rivet is pulled to fix the shower head to the sidewall.

In the case of the conventional rivet-type structure, however, as the rivet insertion hole is widened by thermal expansion, the rivet may fall out. Furthermore, when the rivet is pulled, the end of the rivet insertion hole is widened. Thus, whenever the rivet is removed for maintenance, the corresponding rivet insertion hole is continuously widened.

### RELATED ART DOCUMENT

### Patent Document

Patent Document 1: Korean Patent Application Publication No. 10-2001-0076391 published on Aug. 11, 2001

### SUMMARY

Various embodiments are directed to a shower head which is fixed to a sidewall through a coupling unit for applying pressure to the shower head and the sidewall, and can prevent a coupling unit from falling out due to an end of the coupling unit even though the diameter of an assist groove through which the coupling unit is passed by thermal expansion of the shower head is increased, thereby preventing a separation of the sidewall from the shower head, and a substrate processing apparatus having the same.

In an embodiment, there is provided a shower head which injects process gas into a reaction space within a substrate processing apparatus and is fixed to an upper lid of the substrate processing apparatus by a sidewall. The shower head may include a coupling unit installed through the shower head and the sidewall to apply pressure. A side part of the shower head may include one or more mounting grooves for preventing a separation between the shower head and the sidewall through the coupling unit.

In an embodiment, a substrate processing apparatus may include: a chamber configured to provide a reaction space for a substrate processing process; an upper lid installed at the top of the chamber to seal the reaction space; a susceptor installed in the chamber to support a substrate supplied from the outside; a shower head installed under the upper lid so as to face the susceptor; a sidewall fixing the shower head to the upper lid; and a coupling unit installed through the shower head and the sidewall to apply pressure. A side part of the shower head may include one or more mounting grooves for preventing a separation between the shower head and the sidewall through the coupling unit.

In accordance with the embodiment of the present disclosure, the shower head may be fixed to the sidewall through the coupling unit. Therefore, the end part of the coupling unit can prevent the coupling unit from falling out of the assist groove, even though the diameter of the assist groove through which the coupling unit is passed is increased by thermal expansion, which makes it possible to increase the coupling force between the sidewall and the shower head.

Furthermore, even when a repair work is performed, the diameter of the assist groove through which the coupling unit is passed may not be increased. Although only the end part of the coupling unit is cut, the sidewall can be easily replaced.

### BRIEF DESCRIPTION OF THE DRAWINGS

FIG. 1 is a schematic cross-sectional view of a substrate processing apparatus using plasma according to the related art.

FIG. 2A illustrates that a sidewall and a shower head are fixed through a pin in the substrate processing apparatus according to the related art.

FIG. 2B illustrates that the sidewall and the shower head are fixed through a rivet in the substrate processing apparatus according to the related art.

FIG. 3 is a schematic cross-sectional view of a substrate processing apparatus including a shower head in accordance with an embodiment of the present disclosure.

FIG. 4 is an expanded cross-sectional view of a corner portion of the shower head of FIG. 3 in accordance with the embodiment of the present disclosure.

FIG. 5 is an expanded cross-sectional view of a corner portion of the shower head of FIG. 3 in accordance with another embodiment of the present disclosure.

FIGS. 6A and 6B are diagrams for describing the principle that the shower head is fixed to the sidewall by a coupling unit.

FIG. 7 is a partial exploded perspective view illustrating that the shower head is fixed to the sidewall by the coupling unit.

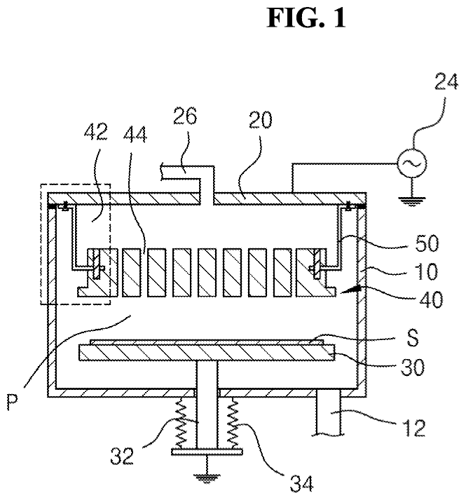

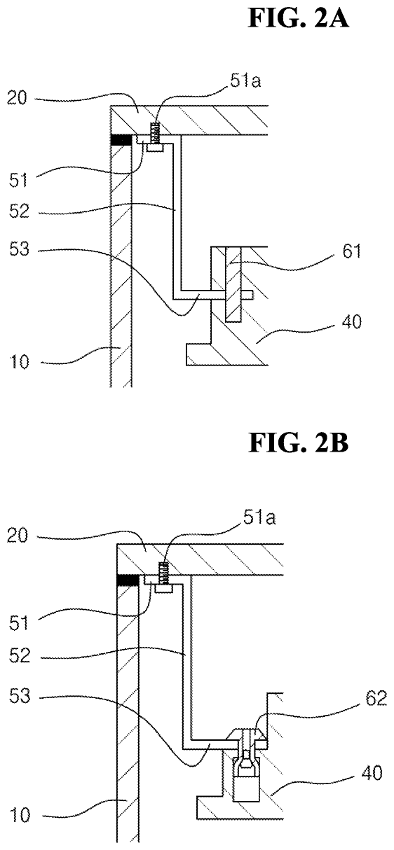

### DETAILED DESCRIPTION

Hereafter, exemplary embodiments of the present disclosure will be described with reference to the accompanying drawings.

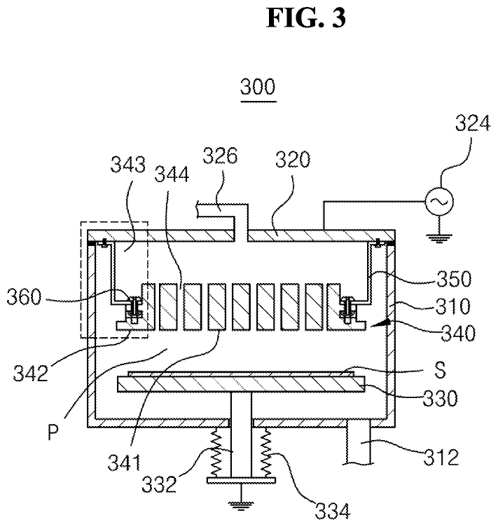

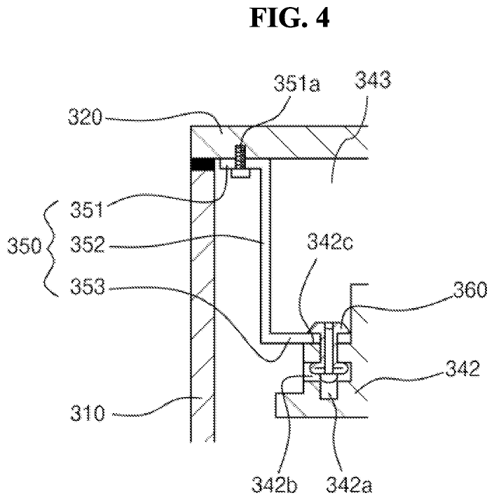

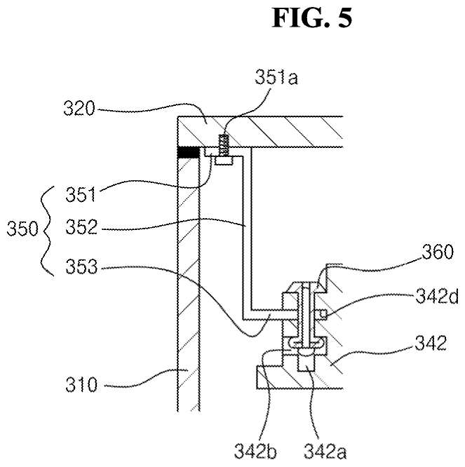

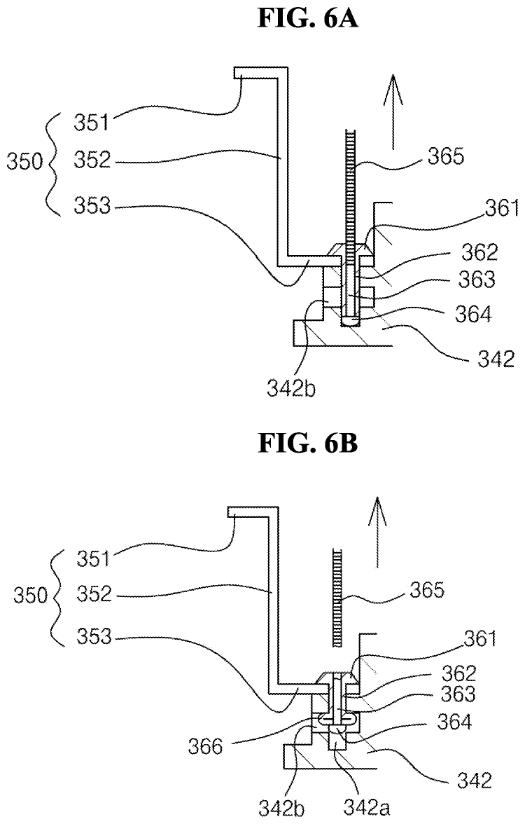

FIG. 3 is a schematic cross-sectional view of a substrate processing apparatus including a shower head in accordance with an embodiment of the present disclosure. FIG. 4 is an expanded cross-sectional view of a corner portion of the shower head of FIG. 3 in accordance with the embodiment of the present disclosure, FIG. 5 is an expanded cross-sectional view of a corner portion of the shower head of FIG. 3 in accordance with another embodiment of the present disclosure, and FIGS. 6A and 6B are diagrams for describing the principle that the shower head is fixed to the sidewall by a coupling unit.

Referring to FIGS. 3 to 5 and 6A and 6B, a shower head fixed to a sidewall by an oarlock in accordance with an embodiment of the present disclosure will be described.

The shower head 340 in accordance with the embodiment of the present disclosure injects process gas into a reaction space P within the substrate processing apparatus 300, and is fixed to the bottom of an upper lid 320 of the substrate processing apparatus 300 through the sidewall 350.

The shower head 340 includes a center part 341 in which a plurality of gas injection holes 344 for injecting process gas into the reaction space are formed and a side part 342 to which a second end part of the sidewall 350 is fixed. At this time, the shower head may have a circular or rectangular shape when seen from the top.

The sidewall 350 includes a first end part 351, the second end part 353 and a connection part 352. The first end part 351 is fixed to the bottom of the upper lid 320 of the substrate processing apparatus 300 through a bolt 351a, and the second end part 353 is fixed to the side part 342 of the shower head 340 to support the shower head 340. The connection part 352 has one end connected to one end of the first end part 351 and the other end connected to one end of the second end part 353.

The first end part 351 of the sidewall is fixed to the bottom of the upper lid 320 through the bolt 351a, and the second end part 353 of the sidewall is fixed to the side part 342 of the shower head 340, in order to provide a space in which reaction gas is diffused between the upper lid 320 and the shower head 340. The sidewall serves to provide a sealed space between the upper lid 320 and the shower head 340, and prevent diffusion of the reaction gas to a sidewall of a chamber 310.

At this time, the sidewall may have a flexible structure in order to minimize thermal stress by thermal expansion or contraction of the shower head.

A coupling unit 360 includes a first end part 361, an outer case 362, an inner shim 363, a protruding end part 364 and a pull-out part 365. When the pull-out part 365 is pulled by a tool after the coupling unit 360 is inserted into an assist groove, the inner shim 363 and the protruding end part 364 are pulled upward. Thus, a portion of the outer case 362 is pressed to form a second end part 366.

Various embodiments may be provided as the coupling unit. In the present disclosure, it is described that an oarlock is used as the coupling unit. Since the structure of the oarlock is publicly known, the detailed descriptions thereof are omitted herein.

In order that the shower head 340 is fixed to the sidewall 350 by the coupling unit 360, the main body of the shower head 340 requires a space in which the second end part 366 of the coupling unit can be formed.

Therefore, the shower head 340 in accordance with the embodiment of the present disclosure includes an assist groove 342a and a mounting groove 342b which are formed at a side surface of the side part 342. The coupling unit 360 may be inserted into the assist groove 342a, and the mounting groove 342b may serve as a space in which the second end part 366 of the coupling unit can be formed.

The shower head 340 is fixed to the sidewall 350 through the following process.

First, the second end part 353 of the sidewall 350 is placed on a sidewall mounting part 342c of the side part 342 of the shower head 340, and the assist groove 342a is formed in the second end part 353 and the side part 342 of the shower head 340, such that the coupling unit can be passed through the assist groove 342a.

The mounting groove 342b serving as a space in which the second end part 366 of the coupling unit may be placed is formed at the side surface of the side part 342 of the shower head 340 by a T-cutter or another tool.

Then, when the pull-out part 365 is pulled by a tool after the coupling unit 360 is inserted into the assist groove 342a, the inner shim 363 and the protruding end part 364 are pulled upward, and a portion of the outer case 362 is pressed to form the second end part 366 of the coupling unit in the mounting groove 342b. Thus, the shower head 340 is fixed to the sidewall 350.

Then, when a repair work is required, only the second end part 366 of the coupling unit may be cut by a T-cutter, and the shower head 340 may be separated from the sidewall 350, which makes it possible to easily perform the repair work.

Therefore, the lifetime of the shower head 340 can be increased except for the case in which a crack occurs in the base material of the shower head 340.

FIG. 4 illustrates the shower head in accordance with the embodiment of the present disclosure, showing that the coupling unit is passed through the shower head 340 and the sidewall 350, with the second end part 353 of the sidewall 350 placed on the sidewall mounting part 342c of the side part 342 of the shower head 340. FIG. 5 illustrates a shower head in accordance with another embodiment of the present disclosure, showing that the coupling unit is passed through the shower head 340 and the sidewall 350, with the second end part 353 of the sidewall 350 inserted into a fixing groove 342d of the side part 342 of the shower head 340.

As illustrated in FIG. 3, the substrate processing apparatus 300 including the shower head in accordance with the embodiment of the present disclosure includes the chamber 310, the upper lid 320, a susceptor 330, the shower head 340 and the sidewall 350.

The chamber 310 provides a reaction space for a substrate processing process. At this time, one side of the bottom surface of the chamber 310 communicates with an exhaust port 312 for exhausting gas from the reaction space.

The upper lid 320 is installed at the top of the chamber 310 so as to seal the reaction space, and serves as a plasma electrode. One side of the upper lid 20 is electrically connected to an RF (Radio Frequency) power supply 324 through a power cable. At this time, the RF power supply 324 generates RF power, and supplies the generated RF power to the upper lid 320 serving as a plasma electrode. Furthermore, the center part of the upper lid 320 communicates with a gas supply pipe 326 that supplies process gas for a substrate processing process.

The susceptor 330 is installed in the chamber 310 and supports a substrate S loaded from the outside. The susceptor 330 serves as a counter electrode facing the upper lid 320, and is electrically grounded through a support shaft 332 supporting the susceptor 330. At this time, the support shaft 332 is surrounded by a bellows 334 that seals the support shaft 332 and the bottom surface of the chamber 310.

The shower head 340 is installed under the upper lid 320 so as to face the susceptor 330. Between the shower head 340 and the upper lid 320, a gas buffer space 342 is formed, to which the process gas supplied from the gas supply pipe 326 installed through the upper lid 320 is supplied. At this time, the process gas is supplied as a gas mixture to the gas buffer space 342, the gas mixture being produced by mixing reaction gas and source gas for forming a predetermined thin film on the substrate S. The shower head 340 injects the process gas into the reaction space through a plurality of gas injection holes 344 communicating with the gas buffer space 342.

The first end part 351 of the sidewall 350 is fixed to the upper lid 320, and the second end part 353 of the sidewall 350 supports the shower head 40. The first end part 351 and the second end part 353 are connected by the connection part 352.

The substrate processing apparatus 300 including the shower head in accordance with the embodiment of the present disclosure, which is illustrated in FIG. 3, has almost the same structure as the substrate processing apparatus using plasma according to the related art, but is characterized in that the shower head 340 is fixed to the sidewall 350 by the coupling unit 360 as described above.

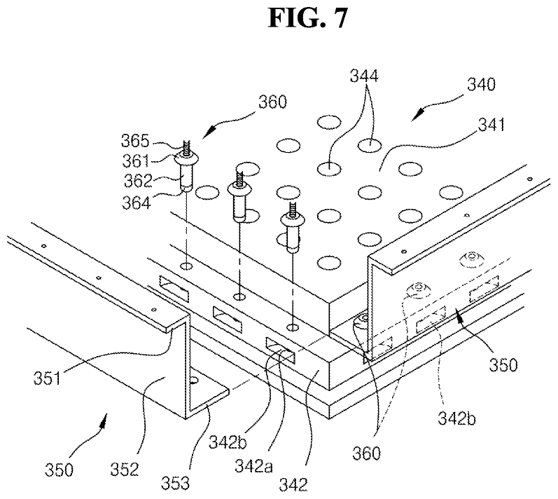

FIG. 7 is a partial exploded perspective view illustrating that the shower head is fixed to the sidewall by the coupling unit.

Referring to FIG. 7, a plurality of assist grooves 342a and a plurality of mounting grooves 342b each serving as a space in which the second end part of the coupling unit can be placed may be formed at the side surface of the side part 342 of the shower head 340.

At this time, proper numbers of assist grooves 342a and mounting grooves 342b may be formed in consideration of a coupling force between the sidewall 350 and the shower head 340 and the stiffness of the shower head 340.

In accordance with the embodiment of the present disclosure, the shower head may be fixed to the sidewall through the coupling unit. Therefore, the second end part of the coupling unit can prevent the coupling unit from falling out of the assist groove, even though the diameter of the assist groove into which the coupling unit is inserted is increased by thermal expansion, which makes it possible to increase the coupling force between the sidewall and the shower head. Furthermore, although only the second end of the coupling unit is cut during a repair work, the sidewall can be replaced, which makes it possible to improve the lifetime of the shower head.

While various embodiments have been described above, it will be understood to those skilled in the art that the embodiments described are by way of example only. Accordingly, the disclosure described herein should not be limited based on the described embodiments.

1. A shower head which injects process gas into a reaction space within a substrate processing apparatus and is fixed to an upper lid of the substrate processing apparatus by a sidewall, the shower head comprising a coupling unit installed through the shower head and the sidewall to apply pressure,
wherein a side part of the shower head comprises one or more mounting grooves for preventing a separation between the shower head and the sidewall through the coupling unit.

2. The shower head of claim 1, wherein the side part of the shower head further comprises a fixing groove into which the sidewall is inserted.

3. The shower head of claim 1, wherein the shower head has an assist groove formed at a bottom surface of the mounting groove, such that the coupling unit passed through the shower head and the sidewall is inserted into the assist groove.

4. . The shower head of claim 1, wherein the coupling unit comprises:
a first end part; and
a second end part configured to provide pressure with the first end part to fix the sidewall and the shower head.

5. The shower head of claim 4, wherein the first end part is located outside the shower head, and the second end part is located on a top surface of the mounting groove.

6. The shower head of claim 1, wherein the coupling unit is an oarlock.

7. The shower head of claim 1, wherein the sidewall has a flexible structure to reduce stress by thermal expansion or contraction of the shower head.

8. A substrate processing apparatus comprising:
a chamber configured to provide a reaction space for a substrate processing process;
an upper lid installed at the top of the chamber to seal the reaction space;
a susceptor installed in the chamber to support a substrate supplied from the outside;
a shower head installed under the upper lid so as to face the susceptor;
a sidewall fixing the shower head to the upper lid; and
a coupling unit installed through the shower head and the sidewall to apply pressure,
wherein a side part of the shower head comprises one or more mounting grooves for preventing a separation between the shower head and the sidewall through the coupling unit.

9. The substrate processing apparatus of claim 8, wherein the side part of the shower head further comprises a fixing groove into which the sidewall is inserted.

10. The substrate processing apparatus of claim 8, wherein the coupling unit is an oarlock.
